(19) United States
(12) Patent Application Publication
(10) Pub. No.: US 2015/0179848 A1
(43) Pub. Date: Jun. 25, 2015

(54) DEPLOYABLE SOLAR PANEL SYSTEM

(71) Applicant: GENERAL ELECTRIC COMPANY, Schenectady, NY (US)

(72) Inventors: Charles Steven Korman, Niskayuna, NY (US); Neil Anthony Johnson, Niskayuna, NY (US); Michael Scott Herzog, Voorheesville, NY (US); Donald Michael Doherty, Schenectady, NY (US); Kevin Sean Myers, Albany, NY (US)

(21) Appl. No.: 14/140,029

(22) Filed: Dec. 24, 2013

(51) Int. Cl. H02S 30/20; H01L 31/18

(52) U.S. Cl. CPC H01L 31/045; H01L 31/18

(57) ABSTRACT

A deployable solar panel system including a basic unit of a plurality of photovoltaic (PV) panels electrically interconnected to each other and mechanically interconnected to each other by a hinge bonded to each PV panel, thereby allowing the basic unit to be folded for transportation and storage into a compact form and then unfolded for installation.

### BACKGROUND OF THE INVENTION

1. Field of the Invention

The invention relates to the installation of solar cell panels, and in particular to a system and method of installing solar cell panels on a low slope surface, such as a rooftop of a commercial building, and the like.

2. Description of Related Art

Currently, there is approximately 11 billion square meters of commercial rooftop surface available worldwide. Tapping even a small fraction of this potential would make a significant impact on the world's energy needs.

On roofs of commercial buildings, which usually have no or low slope, panels are mounted at a desired tilt angle using a dedicated substructure, which adds additional weight to the roof. Mounting a solar array on existing residential buildings does not normally pose a problem with additional weight because the typical residential substructure is built for heavy snow and is capable of supporting the framed solar panels and mounting structure. However, when working on commercial buildings, it is absolutely important that the addition of more weight on the roof be carefully evaluated, especially when it comes to old and/or light-framed, or wood agricultural buildings. In addition, many residential and commercial buildings, particularly in the western parts, and southern parts of the United States, are not designed to handle snow loading and are structurally weaker. Many warehouses and large box stores are not equipped to handle heavy solar systems.

These additional weight loads can be substantial. For example, a method for mounting framed panels on a commercial roof is through the use of plastic troughs, which are filled with gravel or equivalent to secure the array to the roof. This technique can be used so as to avoid damaging the roof by drilled holes to fix a mounting structure. With such systems, additional weight of up to 300 kg/m² can be reached, which needs to be supported by the existing roof structure.

In addition, additional wind loads emerge almost always when additional components are mounted onto a roof. Even if solar panels are mounted in parallel to the roof, the edges are exposed to wind and remarkable loads may be introduced into the roof structure. The impact on the static loading of the building is most obvious looking at elevated mounted photovoltaic (PV) systems on flat roofs of commercial buildings. Due to the elevation of the PV panels, they operate like sails and catch the wind. The occurring stress introduced into the building structure depends on the height of the building and the average local wind speed and is determined according to building codes and standards, following to which the building needs to be statically analyzed.

To meet rooftop wind loading requirements, conventional flat solar panels typically must be secured to the roof or building structure with either expensive, heavy mounting hardware or ballast that is difficult to install and remove, if necessary, for roof repair, and the like. There have been some attempts to eliminate the heavy mounting hardware by simply applying adhesives to the solar panels and then mounting them to the roof. It is noted that these systems lie flat on the roof and may have problems associated with soiling, and the like. In addition, these flat systems produce less energy than systems that are tilted, even slightly, toward the sun.

Further, a heavy ballasted PV system can damage a membrane roof as the system drags across or compresses the roof. Slip sheets are normally used underneath the system to avoid damage to the roof. Together with the need for tilting, the resulting mounting systems require a substantial investment in labor, hardware, design and other balance of system costs.

The other aspect of the existing art is that the mounting structure is usually separate from the active PV modules and then the individual PV modules are mounted down onto the mounting structure and wired together, all during installation. This method of installation is both cumbersome and costly.

### BRIEF SUMMARY OF THE INVENTION

The inventors have recognized that a lightweight photovoltaic (PV) module that does not require an expensive racking system will result in the lowest installed cost, particularly for a low slope commercial rooftop.

In accordance with the invention, the costs and complexity associated with installing conventional solar cell panels is reduced by a solar cell system that includes a plurality of solar cell panels that are mechanically and electrically coupled to each other prior to shipment, while capable of being folded in a stacking arrangement within a packaging container during shipment, and unfolded and deployed at a desired tilt angle during installation at the installation site without the need for a conventional heavy mounting system.

In one aspect, a deployable solar panel system comprises a basic unit of a plurality of photovoltaic (PV) panels are electrically interconnected to each other by a dc bus and an optional intermediate dc/dc converter, and mechanically interconnected to each other by a hinge bonded to each PV panel, thereby allowing the basic unit to be folded for transportation and storage into a compact form and then unfolded for installation.

In another aspect, a method of installing a deployable solar cell system comprises forming a basic unit of a plurality of photovoltaic (PV) panels electrically interconnected to each other by a dc bus and an intermediate dc/dc converter and mechanically interconnected to each other by a hinge bonded to each PV panel, thereby allowing the basic unit to be folded for transportation and storage into a compact form and then unfolded for installation.

### BRIEF DESCRIPTION OF THE DRAWINGS

FIG. 1 is a perspective view of a deployable solar panel system according to an embodiment of the invention;

FIG. 2 is a perspective view of two (2) basic units comprising four (4) PV panels mechanically and electrically interconnected together according to an embodiment of the invention;

FIG. 3 is an isometric view of the PV panel according to an embodiment of the invention;

FIG. 4 is a perspective view of a lightweight metal substrate with a honeycomb core for mounting a sheet of solar cells thereto, a frame member and hinges mounted to the frame member according to an embodiment of the invention;

FIG. 5 is an enlarged view of the lightweight substrate and the frame with the hinges mounted thereto;

FIG. 6 is a cross-sectional view of the lightweight panel with the honeycomb core taken along line 6-6 of FIG. 5;

FIG. 7 is a X-ray image of the honeycomb core of the invention;

FIG. 8 is an enlarged partial view of the hinge mechanically interconnecting two PV panels to each other;

FIG. 9 is an isometric view of the basic unit of PV modules mounted to a roof structure using a plurality of pad attach assemblies according to an embodiment of the invention;

FIG. 10 is an enlarged partial view of the pad attach assembly according to an embodiment of the invention;

FIG. 11 is an exploded view of the pad attach assembly according to an embodiment of the invention;

FIG. 12 is an isometric view of a basic unit of PV panels mounted to a roof structure using a linear strip having a plurality of pad attach assemblies according to an alternate embodiment of the invention;

FIG. 13 is an isometric view a reinforcement bar for providing additional structural reinforcement to the basic unit according to an embodiment of the invention;

FIG. 14 is an enlarged partial view of the reinforcement bar of FIG. 13;

FIG. 15 is a side view of the reinforcement bar mounted to the pad attach assembly according to an embodiment of the invention;

FIG. 16 is an enlarged view of whip connectors for electrically interconnecting adjacent PV panels in series according to an embodiment of the invention;

FIG. 17 is a schematic diagram of electrically interconnecting a plurality of basic units of PV panels in series according to an embodiment of the invention; and

FIG. 18 is a schematic diagram of electrically interconnecting a plurality of basic units of PV panels in series according to an alternate embodiment of the invention.

### DETAILED DESCRIPTION OF THE INVENTION

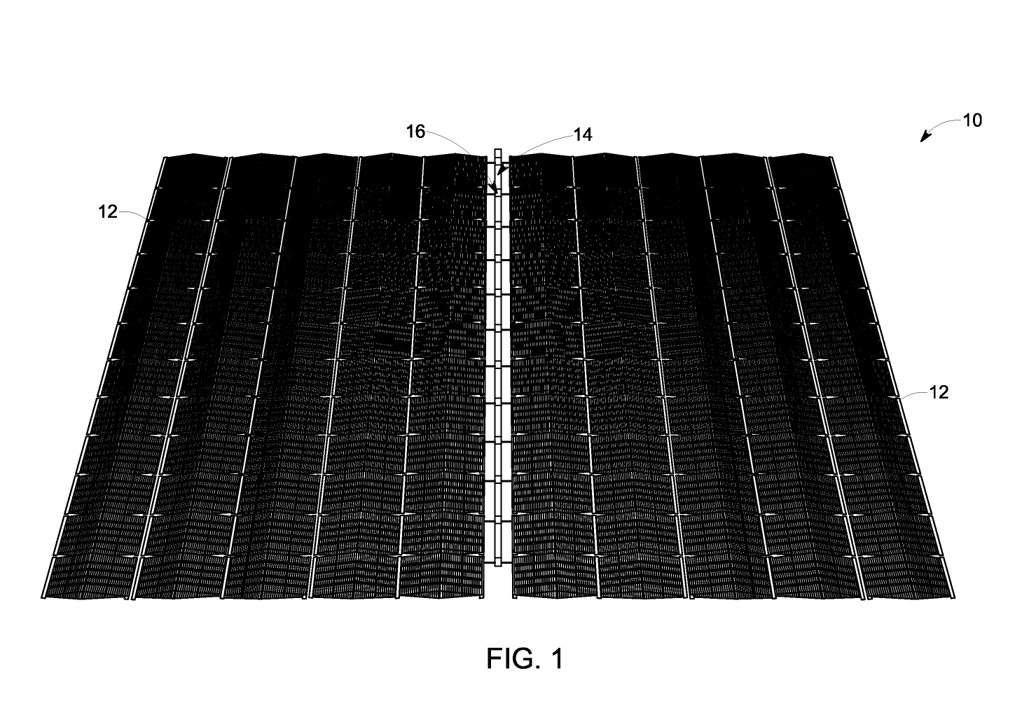

FIG. 1 shows a detailed view of a deployable solar panel system 10 according to an embodiment of the invention. In general, the deployable solar panel system 10 comprises three major system components: a) a folding string of an even number of photovoltaic (PV) panels 12; b) a dc bus 14, and c) an optional dc/dc optimizing converter 16.

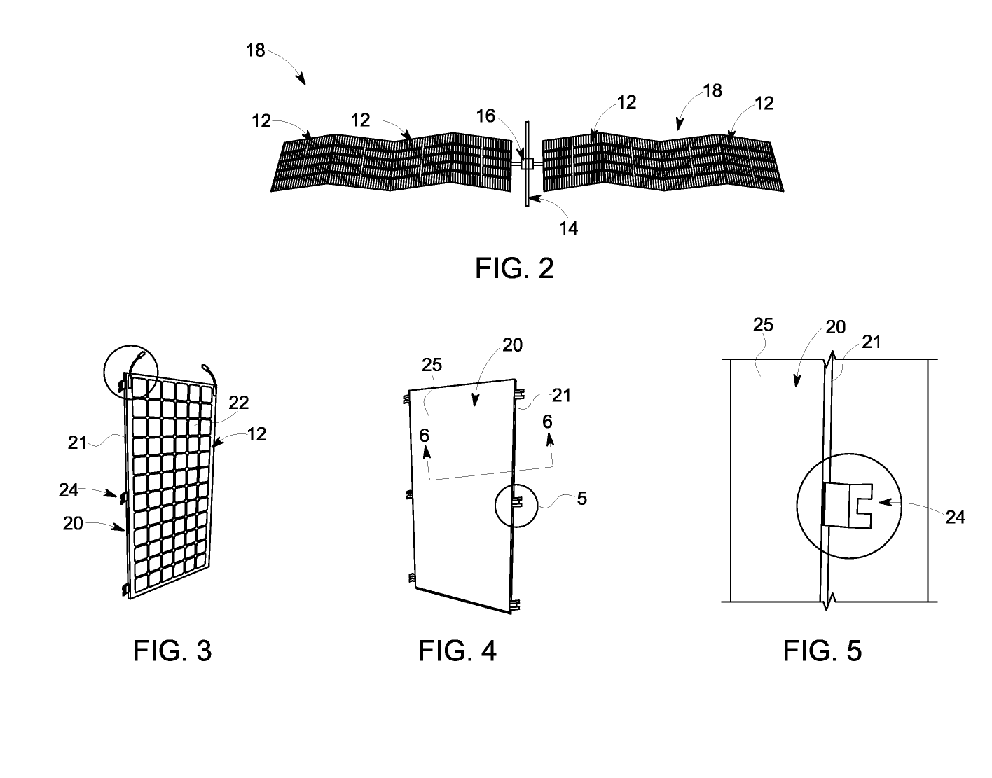

Referring now to FIG. 2, the basic unit of the system 10 is the folding string of an even number of photovoltaic (PV) panels 12 that are both mechanically and electrically connected as a basic unit 18 prior to shipment to the installation site. The string of PV panels 12 can be folded for transportation and storage into a compact form and then unfolded for installation onto a rooftop. In the illustrated embodiment, the basic unit 18 is a 1.0-1.2 kW string of four (4) PV panels 12. It is noted that the power is dependent on the choice of solar cell and the size of the panel 12. The PV panel 12 is extremely lightweight (less than 22 pounds).

As shown in FIG. 2, two (2) basic units 18 of a 1.0-1.2 kW string of four (4) PV panels 12 (a total of 2.00-2.4 kW) connected to the 100 A dc bus 14 through the intermediate 2.5 kW dc/dc converter 16. The dc/dc converter 16 is optional. A dc optimizer (not shown) can be used with each panel 12 that will compensate for the different panel orientations within each basic unit 18. The requirement for an even number of PV panels 12 will become clear when the mounting of the system 10 is discussed. The individual PV panels 12 can be electrically interconnected in series or in parallel, or a combination thereof. The preferred orientation as shown for a folding string is east-west, so that alternate PV panels 12 will produce different levels of power due to their solar orientation. Studies show that the mismatch of power is about 1% at an angle of inclination of about seven (7) degrees.

Referring now to FIGS. 3-5, each PV panel 12 is a laminated structure comprised of a lightweight metal substrate 20 and a sheet 22 of solar cells bonded to one side of the metal substrate 20. The metal substrate 20 includes a raised metal frame 21 around the perimeter of the metal substrate 20, and a hinge 24 bonded to the frame 21 using well-known means, such as welding and the like. The frame 21 acts as a mounting lip to keep the sheet 22 of solar cells in place.

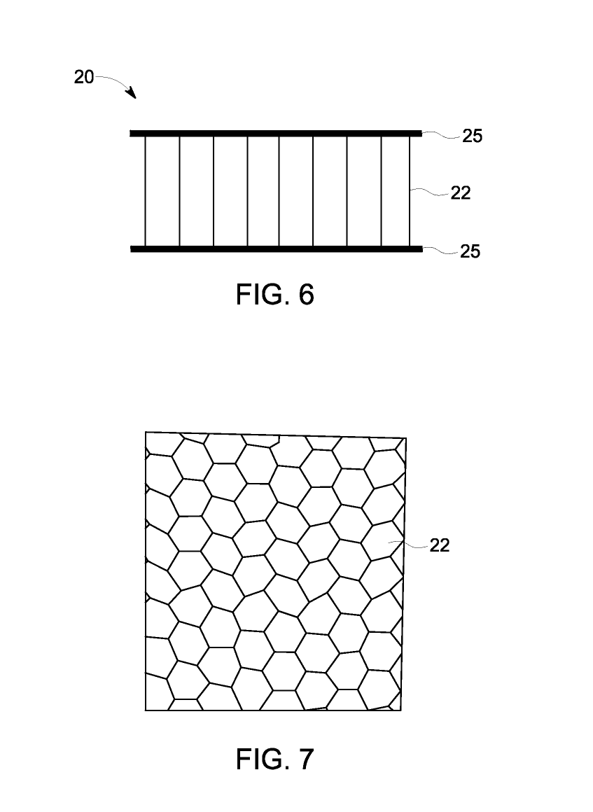

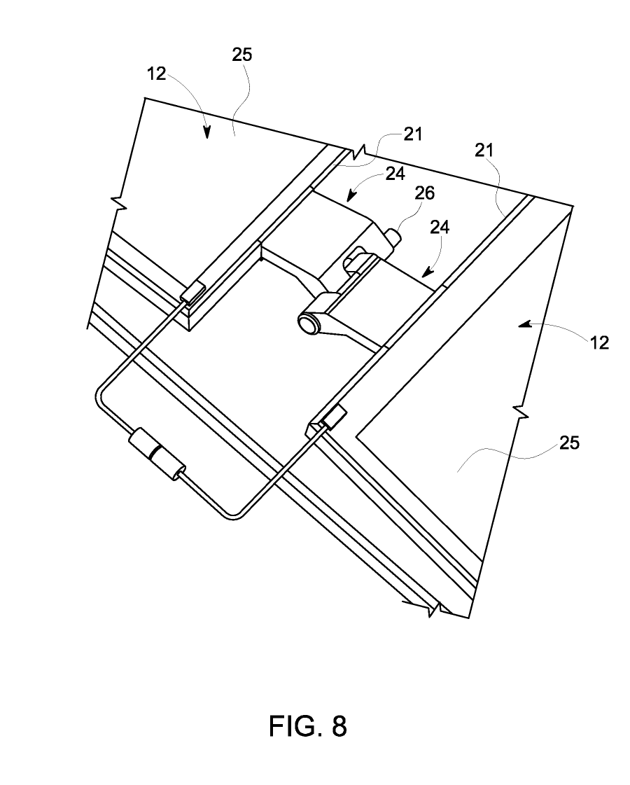

As shown in FIGS. 4-7, the lightweight metal substrate 20 is comprised of a honeycomb core 22 and two facing sheets 25 bonded to the honeycomb core 20 using a suitable adhesive, such as Ethylene Vinyl Acetate (EVA) adhesive, and the like. The pattern of the honeycomb core 22 can be non-uniform to provide flexural stiffness in a preferential direction, as shown in FIG. 5. The facing sheets 25 can have a uniform thickness that is less than 1 percent of the thickness of the honeycomb core 20. The structure of the honeycomb core 20 can be extended to other low density options, not limited to a honeycomb design. The honeycomb core 22 enables the metal substrate 20 to be extremely lightweight (less than 20 lbs).

The honeycomb core 22 is made of an aluminum alloy selected to minimize weight and provide sufficient strength. Other materials may be used for the honeycomb core 22 to tradeoff weight and strength. The thickness of the honeycomb core 22 is a design choice based on the expected loading conditions. The facing sheets 25 are made of an aluminum alloy. However, other materials may be used for the facing sheets 25, so long as they are compatible with the adhesive and the material of the honeycomb core 22.

A plurality of hinges 24 are bonded to the frame 21 of each PV panel 12. The hinges 24 can be electrically bonded to the frame 21 using any well-known means in the art, such as by welding and the like. In the illustrated embodiment, three (3) hinges 24 are bonded to each side of the metal substrate 20. Each hinge 24 is identical to each other, which allows for a single part to be inventoried, rather than multiple parts needed with conventional hinges. The hinge 24 is made of a lightweight material, such as an aluminum alloy. The hinge 24 may be constructed of other materials that are compatible with the adhesive and have sufficient strength to withstand loading. The hinge 24 is designed to withstand wind and snow loading of 50 pounds of force per square foot.

The hinge 24 has a very unique design that allows the PV panels 12 to be standardized. This design has opposing hinges 24 that are identical joined by a clevis pin 26 through the center, as shown in FIG. 8. This allows for a single hinge 24 to be constructed and used at all attachment locations in the system 10. It also reduces the confusion around which PV panel 12 needs to be used in which location and the correct orientation of the PV panel 12 because all the PV panels 12 are identical and can only be attached in one orientation relative to each other. In order to use the same hinge 24, every other PV panel 12 is rotated 180 degrees when making the connection with the clevis pin 26.

The PV panel 12 can be assembled by welding the hinges 24 to the frame 21 that defines the perimeter of the substrate 20. The honeycomb core 22 is then dropped into the interior of the frame 21 and the top and bottom sheets 25 are laminated to the core 22. The bonding of all the elements of the metal substrate 20 using welding ensures that all the elements of the metal substrate 20 are electrically connected together.

Currently, greater than 60% of all commercial rooftop area is covered by some type of polymer membrane and 90% of all new roofing jobs use a membrane roofing system with the white thermoplastic polyolefin (TPO) membrane having by far the largest volume. A typical TPO membrane roof will have a warranty of 25 years or better. There are a number of ways these warranties may be voided: penetrations, excessive surface abrasion, excessive compression due to heavy objects, excessive temperatures (beyond normal ambient). The installation of traditional solar systems which require roofing penetrations or heavy ballasting have the potential to reduce membrane life. Even some building integrated photovoltaic (BIPV) products that are integrated with membrane roofing can raise membrane roofing temperatures to greater than 170 degrees F.

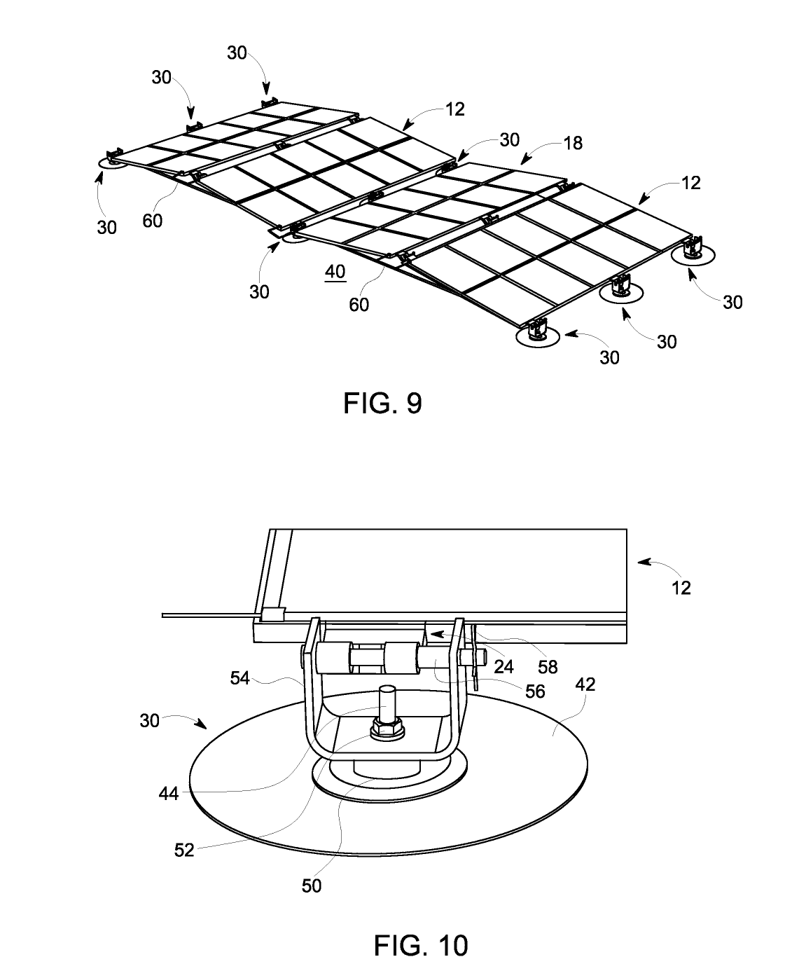

Referring now to FIGS. 9-11, the folding PV panels 12 are attached to the roof using a plurality of pad attach assemblies 30. Because the folding PV panels 12 have a uniform known geometry, the location of the pad attach assemblies 30 is also known. It is noted that the spacing 32 of the pad attach assemblies 30 determines the folding angle 34 of the basic unit 18 with respect to the roof structure (not shown), which is between about 5 degrees and about 10 degrees. In one embodiment, the folding angle 34 is about seven (7) degrees.

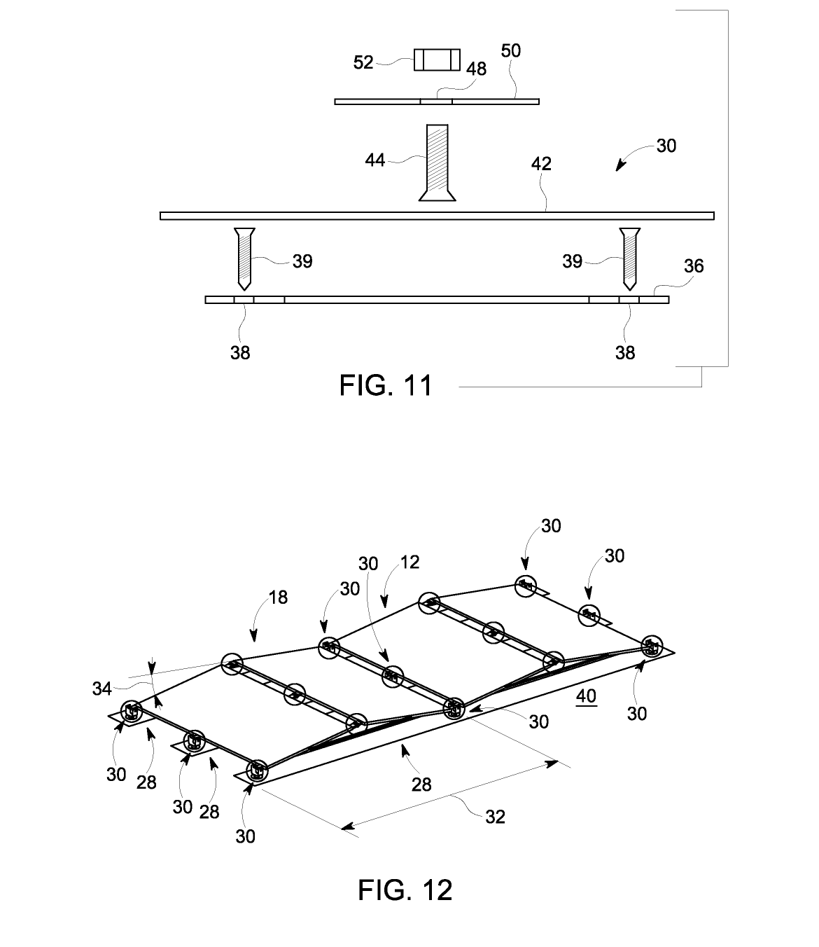

As shown in FIGS. 10 and 11, each pad attach assembly 30 includes a round metal ring 36 with a plurality of apertures 38 for accommodating a fastener 39, such as a screw and the like, for attaching the metal ring 36 to the membrane roof. The round metal ring 36 is coated with a TPO powder. A round cover 42 made of TPO material is bonded and sealed to the powder coated metal ring 36 using a suitable process, such as a Rhinobond® process, and the like. A threaded fastener 44, such as a screw and the like, rests on top of the round cover 42 and passes through an aperture 48 in a metal plate 50. A nut 52 can be threaded onto the threaded fastener 44 to hold the threaded fastener 44 in place. The metal plate 50 is also coated with TPO powder and bonded and sealed to the metal cover 42 using a similar process as the metal ring 36.

As shown in FIG. 10, a U-bracket 54 is then placed over the threaded fastener 44 and a nut 56 is then threaded onto the threaded fastener 44 to secure the U-bracket 54 to the pad attach assembly 30. The U-bracket 54 can be previously attached to the hinge 24 on each PV panel 12 before shipment to the installation site. A clevis pin 56 and cotter pin 58 can be used to attach the PV panel 12 to each pad attach assembly 30 using the same identical hinge 24 that is shown in FIG. 8. By attaching the U-bracket 54 to each PV panel 12 prior to assembly, the basic unit 18 of PV panels 12 to be easily assembled at the installation site by simply placing the U-bracket 54 over the threaded fastener 44 of each pad attach assembly 30.

In an alternate embodiment of the invention, the PV panels 12 are attached to a membrane roof (not shown) using a linear strip 28 with a plurality of round thermoplastic polyolefin (TPO) pad attach assemblies 30, as shown in FIG. 12. In the illustrated embodiment, three (3) linear strips 28 each have three (3) pad attach assemblies 30 for attaching the basic unit 18 of four (4) PV panels 12 to the membrane roof. The linear strips 28 can be fabricated of thermoplastic polyolefin (TPO) material or a material compatible with a given type of membrane roof. Installation of a TPO membrane roof involves a heat sealing process to merge sheets of overlapping roofing material. The interface bond is as strong as the material itself. Some roofing companies also offer TPO-based products that can seal penetrations such as pipes using a similar heat sealing process. The linear strips 28 allow for quicker installation compared to a larger number of round or square pad attachments.

The linear strip 28 runs the length of the basic unit 18 and is screwed down and then covered in much the same way the round pad covered the pad attach assembly 30 so that the linear strip 28 is weather tight. It is noted that the linear strip 28 serves two purposes: 1) attachment of the PV panels 12 to the roof, and 2) setting the folding angle 34. Also, the speed of attachment is far greater with the linear strip 28, which is similar to sealing a roof seam, rather than dealing with many individual round pads as in conventional mounting pads. Thus, the installation now becomes far simpler with the process for attaching the linear strip 28 being similar to that used to adhere the roofing seams allowing the attachment process to be made in a series of passes using high-end heating equipment that works faster. The advantages of the linear strip pad 28 are non-penetrating and non-ballasted mounting system, compatibility with existing membrane roof material, and reduced installation time compared to individual conventional mounting pads.

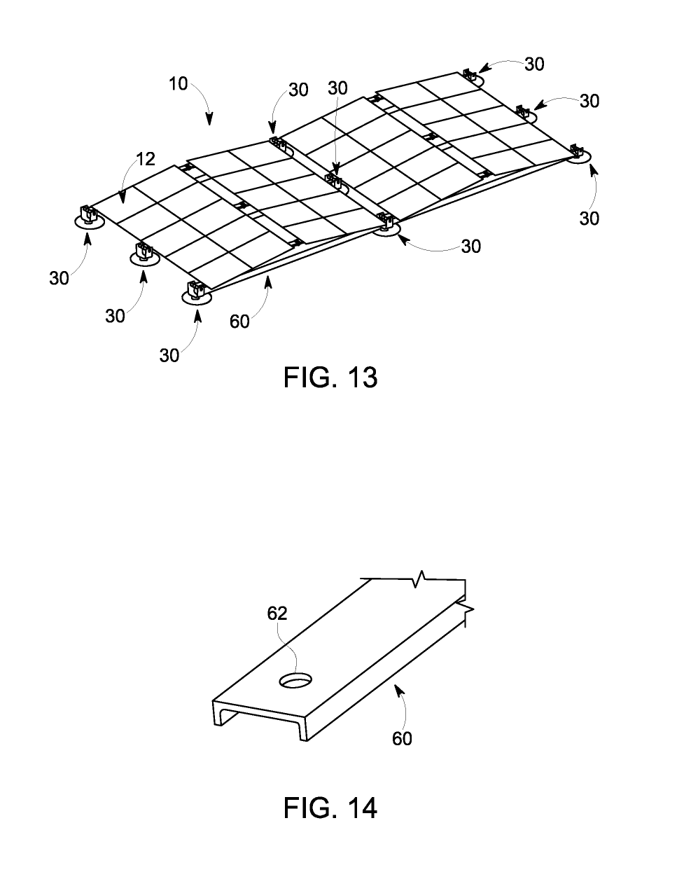

It may be necessary to provide structural reinforcement to the PV panels 12, especially in locations with snow and high wind conditions can be expected. To this end, a reinforcement bar 60 can be mounted on each side of the PV panels 12, as shown in FIGS. 13-15. A single reinforcement bar 60 can be provided for each side of the basic unit 18 of PV panels 12. In the illustrated embodiment, the reinforcement bar 60 is C-shaped in cross-section. However, it will be appreciated that the invention is not limited by the cross-sectional shape of the reinforcement bar 60, and that other shapes are possible. The reinforcement bar 60 can be attached directly to pad attach assembly 30. Specifically, the reinforcement bar 60 may include an aperture 62 that can be positioned over the threaded fastener 44 of the pad attach assembly 30. The reinforcement bar 60 can be positioned between the U-bracket 54 and the metal plate 50 of the pad attach assembly 30, as shown in FIG. 15.

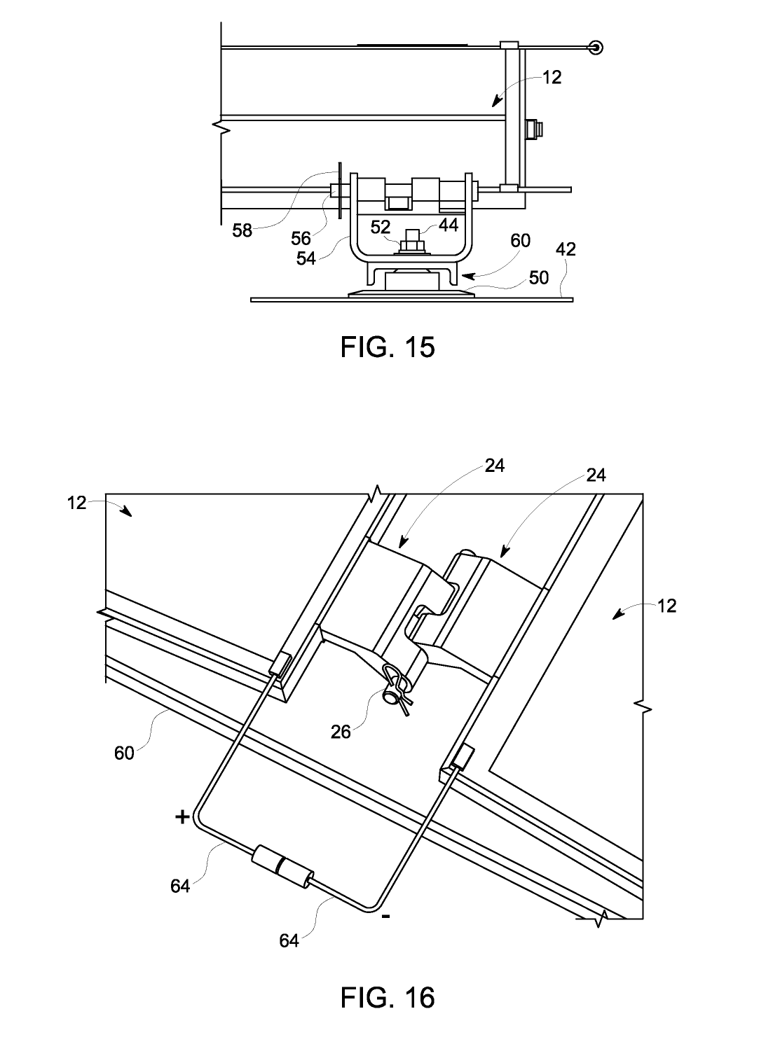

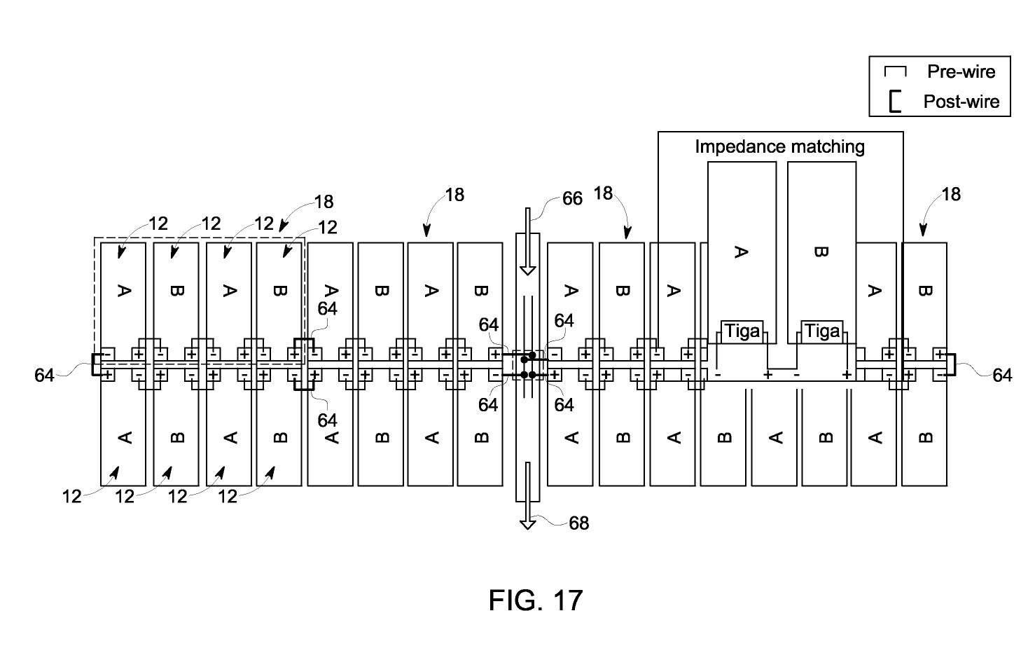

Referring now to FIG. 16, each PV panel 12 has connector whips 64 on board that snap together in a plug and play fashion to electrically connect each PV panel 12 in series to an adjacent PV panel 12. In this manner, the basic unit 18 of PV panels 12 can be easily electrically coupled to each other by using the connector whips 64. In the same manner, multiple basic units 18 of PV panels 12 can be electrically coupled to each other using the coupler 64, as shown in FIG. 14. For example, a basic unit 18 of four (4) PV panels 12, i.e., two (2) “A” PV panels 12 and two (2) “B” PV panels shown within the dashed lines in FIG. 17, configured to produce 1 KW at 200V can be electrically coupled in series using the coupler 64 to three other basic units 18 for a total of 4 KW at 1000V (800V=4×200V). The four (4) basic units 18 can be electrically coupled to another four (4) basic units 18 through a 8 KW parallel bus 66 using the coupler 64 to a 30 KW inverter 68. In this manner, a single coupler 64 can be used to easily connect eight (8) basic units 18 of PV panels 12 for a total of 8 KW at 800V. It will be appreciated that the invention is not limited by the example discussed above, and that the principles of the invention can be practiced with PV panels with different output ratings as will be developed in the future.

It is noted that the “A” panels have the same orientation to the sun and the “B” panels have the same orientation. That is, the “A” panels are facing east, while the “B” panels are facing west, or vice versa. As a result, an impedance mismatch of about 1% occurs between the “A” panels and the “B” panels. This mismatch can be compensated by including dc-dc optimizers at each individual panel, or changing the wiring scheme as described below.

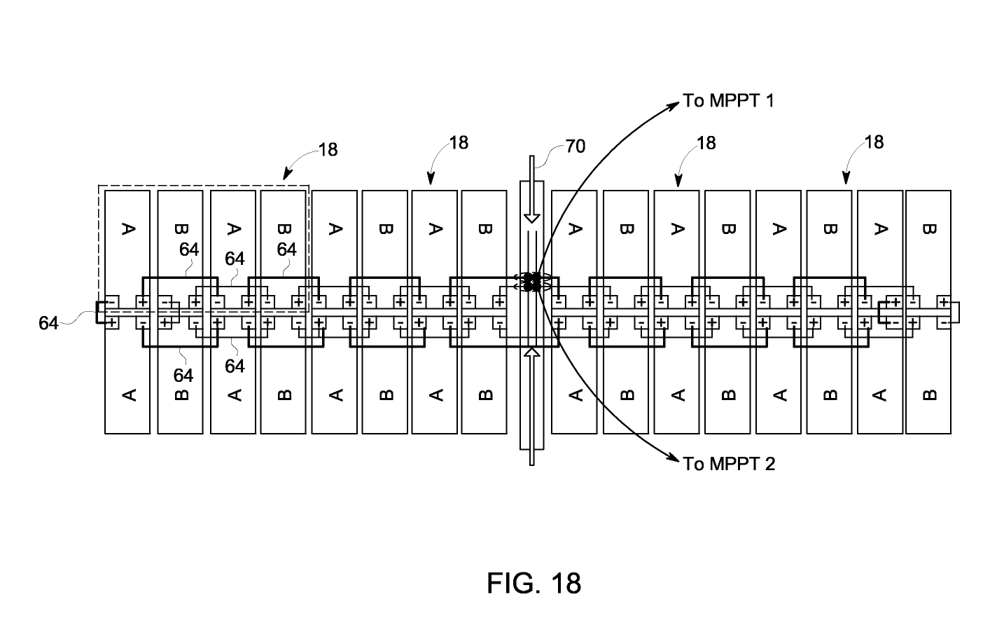

Referring now to FIG. 18, an alternate wiring scheme is shown that alleviates the impedance mismatch between the “A” and “B” panels shown in FIG. 17. Specifically, the “A” PV panels 12 from one basic unit 18 are coupled to each other and the “B” PV panels 12 from the same basic unit 18 are also coupled to each other. Multiple basic units 18 are coupled to each other using a pair of 2 KW MPPT connection points 70, rather than the 8 KW parallel bus 66 in the embodiment of FIG. 17. Although additional wiring is required in the embodiment of FIG. 18, impedance matching is not needed in this embodiment, unlike the embodiment shown in FIG. 17.

The invention is directed to an innovative deployable solar panel system 10 that is designed for rapid and low cost installation onto a low slope roof consists of individual PV panels 12 that are mechanically interconnected using flexible hinges 24. The PV panel 12 is a lightweight design that consists of a honeycomb core 20 sandwiched between two thin facing sheets 22. The honeycomb sandwich structure provides sufficient strength under snow and wind loading on the panels while maintaining a low weight. The hinge 24 is integrated into the honeycomb core 20 such that the panel 12 and hinge 24 are deployed as a single unit. The hinge 24 is a unique design that allows all the panels 12 to be standardized. The panels 12 are mechanically interconnected by inserting a pin 26 between the hinges 24 on adjacent panels 12. This allows a basic unit 18 of four (4) PV panels 12 to be folded for transportation and storage into a compact form and then unfolded for installation onto a membrane roof by strip pads 28 that are attached to the roof using a sealing process that does not require penetration of the roof membrane.

The basic units 18 are also electrically interconnected in either a series or parallel fashion providing a dc output power. Multiple folding basic units 18 are connected to a dc bus 14 that is affixed to the membrane roof through dc/dc converters 16 that provide maximum peak power tracking (MPPT) to optimize solar electric output while maintaining a fixed dc voltage (e.g. 500Vdc). This distributed power architecture minimizes wiring and electrical connection complexity while providing peak electrical performance. Relative to a traditional ballasted commercial rooftop system, the deployable solar panel system 10 of the invention can be installed in a fraction of the time and has 2-4× lighter weight, and provides 10% more energy than a traditional rooftop system.

There are several issues/problems that the invention addresses that will provide commercial differentiation. The first relates to weight. Many buildings not designed to handle heavy snow loads, e.g. in the south, southwest, and west are also unable to structurally handle the heavy lead of a traditional ballasted solar system. The invention allows a system to be structurally attached to a membrane roof without the need for ballasting and heavy metal racking hardware resulting in up to a 4× decrease in weight per unit area. The invention also addresses related problems associated with damage to membrane roofing caused by heavy ballast (due to movement and shifting on the roof). Also, traditional commercial rooftop systems have many components and complicated wiring schemes leading to high installation costs. The folding basic unit 18 of PV panels 12 reduces the number of components that have to be handled (by 4× because a basic unit 18 has four (4) PV panels 12) and the bus architecture provides a uniform process for routing dc power onto the roof. The folding array architecture also increases the energy density of a rooftop solar system because it is does not self-shade, and therefore does have wasted space (e.g. large spaces between rows of modules).

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A deployable solar panel system comprising a basic unit of a plurality of photovoltaic (PV) panels electrically interconnected to each other and mechanically interconnected to each other by a hinge bonded to each PV panel, thereby allowing the basic unit to be folded for transportation and storage into a compact form and then unfolded for installation.

2. The system according to claim 1, wherein each PV panel comprises a honeycomb core between two facing sheets.

3. The system according to claim 2, wherein the honeycomb core has a non-uniform pattern.

4. The system according to claim 2, wherein the facing sheets have a thickness that is less than 1 percent of a thickness of the honeycomb core.

5. The system according to claim 2, wherein the honeycomb core is bonded to the facing sheets.

6. The system according to claim 2, wherein a portion of the hinge is bonded to the facing sheets.

7. The system according to claim 1, further comprising a linear stri for mounting each PV panel to a roof structure.

8. The system according to claim 7, wherein the linear strip includes a plurality of pad attach assemblies for attaching each PV panel to the roof structure.

9. The system according to claim 8, wherein a spacing of the pad attach assemblies determines a folding angle of the basic unit with respect to the roof structure.

10. The system according to claim 9, wherein the folding angle is between 5 degrees and 10 degrees.

11. The system according to claim 1, further comprising a reinforcement bar for providing structural reinforcement to the basic unit.

12. The system according to claim 1, wherein each hinge is identical to each other.

13. A method of installing a deployable solar cell system comprises forming a basic unit of a plurality of photovoltaic (PV) panels electrically interconnected to each other and mechanically interconnected to each other by a hinge bonded to each PV panel, thereby allowing the basic unit to be folded for transportation and storage into a compact form and then unfolded for installation.

14. The method according to claim 13, further comprising attaching the basic unit to a roof structure using a linear strip with a plurality of pad attach assemblies.

15. The method according to claim 14, wherein a spacing of the pad attach assemblies determines a folding angle of the basic unit with respect to the roof structure.

16. The system according to claim 15, wherein the folding angle is between 5 degrees and 10 degrees.

17. The system according to claim 13, wherein each hinge is identical to each other.
